(19) United States
(12) Patent Application Publication
(10) Pub. No.: US 2022/0317559 A1
(43) Pub. Date: Oct. 6, 2022

(54) INTERMITTENTLY PHOTOBLEACHED MASKS, METHODS OF FABRICATION AND USES FOR COMPONENT TRANSFER

(71) Applicant: Terecircuits Corporation, Mountain View, CA (US)

(72) Inventor: Jayna Sheats, Palo Alto, CA (US)

(21) Appl. No.: 17/656,515

(22) Filed: Mar. 25, 2022

Related U.S. Application Data
(60) Provisional application No. 63/169,701, filed on Apr. 1, 2021.

(51) Int. Cl. G03F 1/38

(52) U.S. Cl. CPC G03F 1/38

(57) ABSTRACT

Intermittently photobleached mask with photobleachable and photobleached regions are described, as well as their fabrication and use to selectively release components from a substrate. Intermittently photobleached mask may allow a plurality of select components to be released simultaneously from a donor plate comprising a release layer, thereby facilitating component transfer.

### INCORPORATION BY REFERENCE TO ANY PRIORITY APPLICATIONS

Any and all applications for which a foreign or domestic priority claim is identified in the Application Data Sheet or Request as filed with the present application are hereby incorporated by reference under 37 CFR 1.57, and Rules 4.18 and 20.6. U.S. Provisional App. No. 63/169,701, filed Apr. 1, 2021, is hereby incorporated by reference in its entirety.

### BACKGROUND

### Field

This invention is directed to the manufacture of electronic systems composed of multiple different components, including for example displays using individual light emitting diodes, or microelectronic multichip circuits.

### Description of the Related Art

The transfer of microelectronic objects from one surface to another pervades processes of assembly and packaging of functional products, whether they are purely electronic (as in computer motherboards), optoelectronic (as in displays), sensors, or actuators. The physics of patterning systems limits the size of the system that can be made in one integrated parallel process, and process compatibility limits the type of materials. Thus, useful systems require integration at the packaging level.

Integrated circuits, which allow various components (e.g. passive components) to be fabricated with the same techniques as transistors, allowed entire functional circuits to be made with parallel processing; that is, the simultaneous processing of an area, rather than a device. U.S. Pat. Nos. 6,946,178 and 7,141,348 by Sheats et al., which are hereby incorporated by reference, disclose a method of transferring, or printing, thin film devices from a donor substrate (also here called a donor plate), on which the polymeric photoactivated thermal transfer material has been applied in a thin film, onto a target substrate.

Many techniques have recently been used for processing microelectronics, such as serial pick-and-place, laser ablation, stamps and adhesives. However, improved techniques for transferring a selection of components may be beneficial.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

In one aspect, an intermittently photobleached mask is described. The intermittently photobleached mask includes: an intermittently photobleached layer comprising a photobleachable material; wherein the intermittently photobleached layer comprises photobleached regions at least partially transparent to a release wavelength of light; and wherein the intermittently photobleached layer comprises non-photobleached regions substantially opaque to the release wavelength of light; and a substrate disposed over the intermittently photobleached layer.

In some embodiments, the photobleachable material comprises a base polymer and a polycyclic aromatic hydrocarbon compound. In some embodiments, the polycyclic aromatic hydrocarbon compound is selected from the group consisting of an acene, a tetracene, a pentacene, a rubrene, an anthradichromene, a dianthrone, and combinations thereof. In some embodiments, the polycyclic aromatic hydrocarbon compound is selected from the group consisting of 9,10-dimethylanthracene (DMA), 9,10-diphenylanthracene (DPA), 1,4,9,10-tetraphenylanthracene, 5,12-diphenyltetracene, and combinations thereof. In some embodiments, the polycyclic aromatic hydrocarbon compound is substituted by a substituent selected from the group consisting of an alkyl, an aryl, a siloxane, and combinations thereof. In some embodiments, the siloxane is substituted with a substituent selected from the group consisting of a polyacetylene, a fluoropolymer, a poly(norbornene) and combinations thereof. In some embodiments, the base polymer comprises a polymer selected from the group consisting of an acrylate polymer, a siloxane polymer, and combinations thereof. In some embodiments, the acrylate polymer is selected from the group consisting of poly(methyl methacrylate) (PMMA), poly(ethyl methacrylate) (PEMA), poly(butyl methacrylate) (PBMA) and combinations thereof.

In some embodiments, the release wavelength of light is from about 250-370 nm. In some embodiments, the photobleached regions are at least about 60% transparent to the release wavelength of light. In some embodiments, the non-photobleached regions are at most about 10% transparent to the release wavelength of light. In some embodiments, the substrate is transparent to the release wavelength of light.

In another aspect, a process of using an intermittently photobleached mask is described. The process includes: disposing an intermittently photobleached mask over a transfer assembly comprising a donor plate, a release layer disposed over the donor plate and plurality of components disposed over the release layer; wherein the plurality of components comprise at least one select component disposed over and at least partially overlapping with at least one select release layer region; and wherein photobleached regions are aligned with the at least one select release layer region; and directing a release wavelength of light through the photobleached regions to the at least one release layer region thereby degrading the at least one release layer region and forming at least one released component.

In some embodiments, the process further comprises transferring the at least one released component to a receiving substrate. In some embodiments, the at least one released component comprises a plurality of released components, and wherein the plurality of released components are transferred simultaneously to a receiving substrate. In some embodiments, the process further comprises directing the release wavelength of light through a second mask to the photobleached regions. In some embodiments, the second mask prevents exposure of additional photobleached regions of the intermittently photobleached mask to the release wavelength of light. In some embodiments, the process further comprises moving the second mask relative to the intermittently photobleached mask and the transfer assembly subsequent to directing the release wavelength of light through the second mask, wherein relative positions of the intermittently photobleached mask and the transfer assembly are substantially the same. In some embodiments, the process further comprises applying heat to the at least one release layer region. In some embodiments, the release wavelength of light is directed through the substrate to the at least one release layer region.

In another aspect, a process of fabricating an intermittently photobleached mask is described. The method includes: providing photobleachable layer disposed over a substrate, wherein the photobleachable layer is substantially opaque to a release wavelength of light; exposing the photobleachable layer to an atmosphere comprising oxygen gas; and irradiating select regions of the photobleachable layer to form an intermittently photobleached layer comprising photobleached regions at least partially transparent to the release wavelength of light.

In some embodiments, the process further comprises depositing the photobleachable layer over the substrate. In some embodiments, the atmosphere is air or an oxygen rich atmosphere. In some embodiments, irradiation is performed at a bleaching wavelength from 250-550 nm.

### BRIEF DESCRIPTION OF THE DRAWINGS

These and other features, aspects, and advantages of the present disclosure are described with reference to the drawings of certain embodiments, which are intended to illustrate certain embodiments and not to limit the invention.

FIGS. 1A-1C illustrate a process of increasing the separation of elements and replacing selected elements, according to some embodiments.

FIG. 2 is a graph showing the unirradiated and photobleached absorption spectra of a film of 9,10-diphenylanthracene (“DPA”) in poly(ethyl methacrylate) (“PEMA”).

FIG. 3A is a graph showing the photobleaching kinetics for 9,10-dimethylanthracene (“DMA”) in poly(ethyl methacrylate) (“PEMA”) films and 9,10-diphenylanthracene (“DPA”) in poly(butyl methacrylate) (“PBMA”) films.

FIG. 3B is a graph showing the stability of oxidized DPA to irradiation.

FIG. 4 is an illustration of a photobleached masked arrangement for removing elements from a donor plate, according to some embodiments.

FIG. 5 is an illustration of an arrangement for adjusting the spacing of rows or columns of elements from a donor plate, according to some embodiments.

FIG. 6 is an illustration of a double masked arrangement for removing elements from a donor plate, according to some embodiments.

FIG. 7 is an illustration of a donor plate with elements that that are selected to be removed.

### DETAILED DESCRIPTION

Although certain embodiments and examples are described below, those of skill in the art will appreciate that the invention extends beyond the specifically disclosed embodiments and/or uses and obvious modifications and equivalents thereof. Thus, it is intended that the scope of the invention herein disclosed should not be limited by any particular embodiments described below.

Masks with photobleachable materials are described, as well as their fabrication and use to selectively release components from a substrate. The photobleachable materials of the masks may be intermittently photobleached with a pattern to form an intermittently photobleached mask. While certain regions of the photobleachable material of the mask are bleached and therefore are, or are substantially, transparent to a wavelength of light, other regions remain non-photobleached and therefore are, or are substantially, opaque to the same wavelength of light. The intermittently photobleached regions or pattern may correspond to select components (e.g., defective or non-defective chips) on a substrate (e.g., donor plate). Such an intermittently photobleached mask may be used to release select components from a release layer and thereby transfer the select components in parallel to another substrate.

Assemblies and methods of transferring components using releasable adhesion layers are discussed in U.S. Pat. Nos. 6,946,178 and 7,141,348, which are incorporated herein by reference for all purposes. Triggering processes may be used for separating the transfer components from the adhesion layer for placement on a substrate. As described in U.S. Pat. No. 6,946,178, the triggering processes include exposing the release layer to heat and light in a single step to degrade the release layer. Irradiation with light (e.g., actinic light) may be used to selectively activate the polymer under a device which the user wishes to transfer, while leaving other devices on the same substrate unactivated. Heating the polymer of the release layer (also referred to as a digital release material (e.g., digital release adhesive (“DRA”))) to an appropriate temperature (e.g., less than about 150° C.) may cause the release layer to vaporize and transfer the device to a target substrate in close proximity while leaving the unactivated devices on the donor substrate. By this method, such components or objects (e.g., small integrated circuit chips, for example with lateral dimensions of less than 100 μm that are difficult or impossible to handle effectively by other means such as the pick and place machines) can be placed onto product substrates at high speeds. Among other exemplary applications are light emitting diodes, which for use in active matrix displays may be only a few microns on each side. This process may be referred to as Photoprinting Component Assembly (“PCA”).

Such processes (e.g., the process disclosed in the above referenced patents) allows the selective transfer printing of multiple components from the donor plate according to the irradiation pattern, which is in one embodiment dictated by the apertures in a mask. In one example, a mask is constructed similarly to optical masks for contact or projection lithography, wherein a thin metal film is deposited on a glass or fused silica plate, a resist layer is applied and patterned, and the metal is removed by chemical etching where it is exposed. In some examples, the resist may be exposed by electron beam lithography, by a direct write laser system, or by spatial light modulators. Normally one mask pattern is prepared for each component in a given product, and is re-used through many wafers of incoming components.

However, each source wafer may have some select components (e.g., defective components) that for a particular reason should not ideally be transferred along with the other components of the wafer. Nevertheless, the typical masking process will transfer the select components along with the other components, resulting in the presence of the select components (e.g., defective components) in the product. In order to prevent this, either the select components (e.g., defective components) must be removed before the transfer printing step, or the mask apertures corresponding to the select components' positions must be blocked. Wafer-level testing equipment and procedures are increasingly widely available today, so that a wafer-level map of components (e.g., defective components) is likely to be available. One of the purposes of some embodiments of this disclosure is to provide a cost-effective means to make use of such information to eliminate defective components from products.

In one embodiment, relatively few select components (e.g., defective components or chips) are present in the incoming wafer. In such embodiments, the donor plate, after being populated with components (e.g., chips), may be passed through a station provided with a focused laser beam which can be directed in serial fashion onto any component (e.g., chip) in the array. The select components (e.g., chips) may be simply ejected and collected, such as for recycling or disposal. The target substrate with select components removed will now have vacancies wherever the defective chips were not transferred. One method to fill the vacancies is to use the same serial process: after the normal parallel process, those target substrates which have vacancies are sent through a machine equipped with the directed laser beam to deposit components (e.g., non-defective or good dice) onto the vacancies from another donor plate.

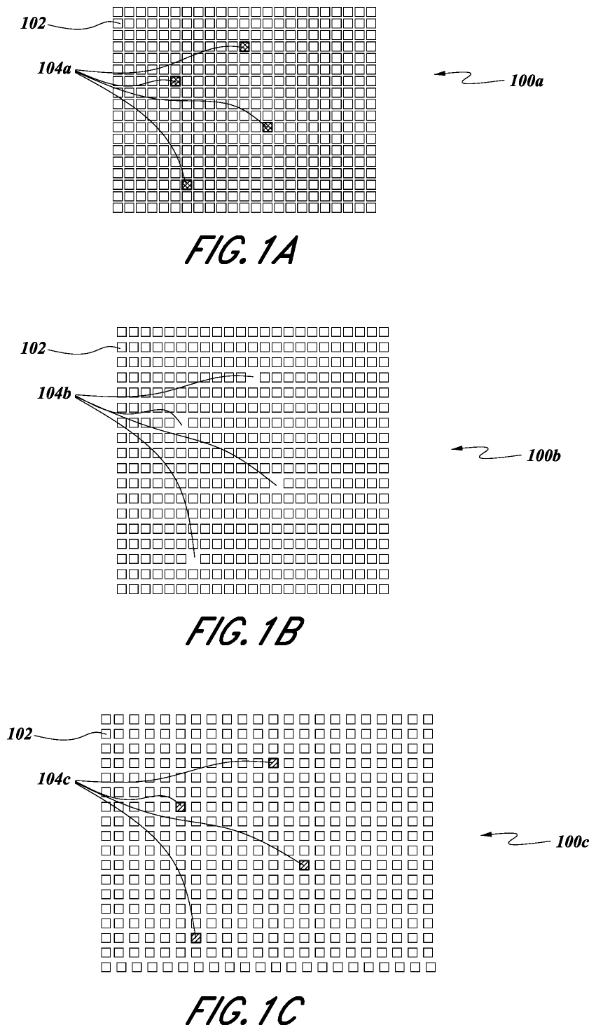

In some embodiments, these steps may be performed in-line with the steps described in U.S. Pat. No. 9,406,644 B2, which is incorporated by reference in its entirety for all purposes. In some embodiments, the components (e.g., chips) undergo two transfers from one release layer-coated (e.g., DRA-coated) donor plate to another in order to increase their spacing in both axes of the wafer plane, as shown in FIGS. 1A-1C, which may be referred to as a pre-press process or a pre-LIFT (Light-Induced Forward Transfer) process. FIG. 1A depicts device 100a with a plurality of components 102 and a subset of select components 104a. The donor plate of the device 100a may then be inverted and passed under a laser processing station, which directs the beam onto the select components 104a (e.g., defective chips). The select components 104a may be ejected and collected into a receptacle. In some embodiments, the removal of the select components 104a may be performed before or immediately before the first re-spacing transfer. After a first re-spacing transfer, FIG. 1B depicts a device 100b with a plurality of components 102 (e.g., chips) residing on a release layer-coated (e.g., DRA-coated) plate with increased spacing in the x direction relative to device 100a, and with voids 104b corresponding to the relative positions of select components 104a. From FIG. 1A to FIG. 1B the components 102 (e.g., chips) are transferred one entire row at a time from one release layer-coated (e.g., DRA-coated) donor plate to another. The remaining components 104b (e.g., chips) are then transferred to achieve the desired spacing in the y direction as depicted in FIG. 1C with device 100c. From FIG. 1B to FIG. 1C the components 102 (e.g., chips) are transferred one entire column at a time from one release layer-coated (e.g., DRA-coated) donor plate to another. This donor plate of device 100c is then passed under another donor plate populated with additional components (e.g., the same type of chip, but with good chips), and a laser beam selects components (e.g., chips) to transfer into the vacant locations on positions 104c of device 100c. This step may require more precise positioning than the previous step in which select components 104a (e.g., chips) are discarded, but is still within the normal process flow for small numbers of defects.

An advantage of such a process as described with regard to FIGS. 1A-1C is a high throughput (relying mainly on parallel irradiation) while eliminating random defects with minimal process complexity (using the serial laser exposure). Although serial processing is not typically the preferred irradiation procedure because it is slower than parallel processing using a mask, the fact that the serial processing does not require a mask can be advantageous for relatively small numbers of transfers. For example, if there were a 5% defect rate in a wafer containing 8000 chips (an 8″ diameter wafer with chip size of about 2 mm×2 mm), one would need to eliminate 400 chips. Using a laser which can address 1000 spots per second, this operation takes 0.4 second, which is comparable to the amount of time required to align a donor plate to the substrate. The movement of a laser beam may be even faster than that, especially for example in an ejection process where very precise alignment is less important, but there will be limits due to the number of pulses per second from the laser. However, such a serial process (e.g. for removing defective chips) may still be substantially faster and/or less expensive than by laser ablation, as disclosed for example in U.S. Pat. No. 8,056,222, which requires much more energy per pulse.

However, in some instances (e.g., donor plates with larger defect densities and/or for small chips of which there are a great number chips on each donor plate) the throughput of such a serial process may be insufficient. As an example, there would be approximately 100,000 0.5×0.5 mm chips in the 8″ wafer, and even at 10,000 per second a process dwell time of 5 seconds may be required for the same 5% defect density; far greater than the sub-millisecond time required for a typical implementation of the PCA process with parallel exposure, and more than 10× greater than the alignment time. In another example, microLEDs, which may typically be about 5×5 μm or even smaller and number in the many millions on one wafer, some chips must be rejected even though they are electrically active because the emission color is outside of specified limits due to process variations during their fabrication. Thus there could be hundreds of thousands or more unacceptable chips in a wafer, even though the conventional electrical defect density may be very low. An additional difficulty with using a focused laser beam to replace the chips arises when they are not square. The irradiation, whether for the PCA process or a simple laser ablation process, must be uniform in order to have accurate placement of the chip. Some components, for example such as ICs and other components such as ceramic passives, may be high aspect ratio rectangles (e.g. 1 mm×4 mm, or other such dimension), and rarely, in fact, is any IC exactly square. There may be adequate process tolerance for rectangles whose aspect ratios depart slightly from 1:1, but it will be very limited. Thus a beam would in general have to be shaped by specific optics for each type of chip. An alternative is to block the mask apertures where chips are not to be transferred. Separate thin film metal masks may be prepared for each incoming wafer, according to the defect map. While this may be effective, the process for making such masks involves several steps which add complexity to the overall process. As such a simplified parallel process may be highly desirable.

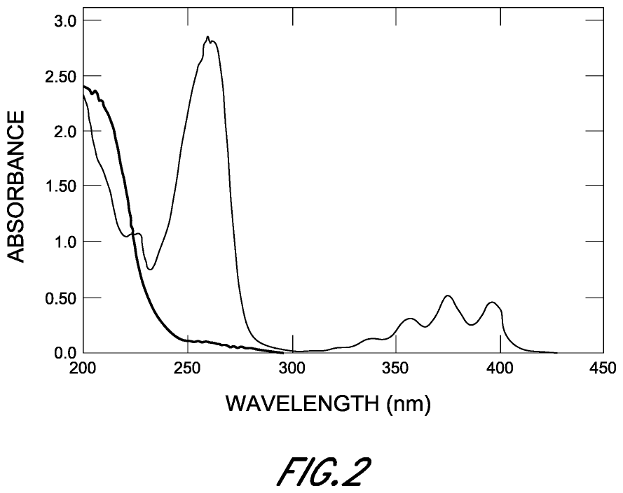

As such, the present disclosure is directed to a mask substrate coated with a light (e.g., UV light) absorbing material (e.g., including a polymer material) whose absorbance can be selectively modified, for example by photobleaching. In some embodiments, the mask substrate is a transparent substrate. In some embodiments, the light absorbing material is a photobleachable material comprising a photobleachable compound. Examples of photobleachable compounds include a polymer containing an anthracene derivative (e.g., 9,10-disubstituted anthracene), as described in U.S. Pat. No. 5,180,655, which is incorporated by reference in its entirety for all purposes. In some embodiments, a thin layer (e.g., less than 1 μm) of such a photobleachable compound (i.e., dye) in a polymer matrix (e.g., inert polymer matrix) may effectively completely or substantially block a select wavelength range of light, such as deep UV (e.g., 248-270 nm) or near UV (e.g., 350-370 nm) light. However, once the photobleachable compound is modified to form a photobleached compound, the polymer matrix may effectively completely or substantially allow a select wavelength range of light to transmit through. For example, FIG. 2 (reproduced from J. R. Sheats, Journal of Physical Chemistry, vol. 94, pp. 7194-7200 (1990)) depicts the photobleaching of a 0.82 μm thick film of 15.4 weight % 9,10-diphenylanthracene in poly(ethyl methacrylate), irradiated with 47 J/cm² at 365 nm under normal atmosphere (i.e., atmosphere comprising oxygen). This dose was used to obtain nominally complete bleaching, wherein most of the reaction occurs with about 500 mJ/cm². This dose can be reduced to less than 200 mJ/cm² if an atmosphere of oxygen is used. Note that the absorbance in the deep UV is stronger than the data indicate because of limitations in the spectrometer above an optical density of 2.2. As such, in the absence of oxygen 9,10-substituted anthracenes are very photostable and can be used to effectively block UV light. However, in the presence of oxygen 9,10-substituted anthracenes efficiently form an endoperoxide which is highly transparent (and photo stable) both in the deep-UV and near-UV.

In some embodiments, the select wavelength of light selected to be blocked by the photobleachable compound and transmitted through the photobleached compound is a wavelength used to aid in the decomposition of a release layer. In some embodiments, the release wavelength is, or is about, 180 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm or 450 nm, or any range of values therebetween. In some embodiments, the photobleached regions that include the photobleached compound are, are about, are at least, or are at least about, 40%, 50%, 55%, 60%, 65%, 70%, 75%, 80%, 85%, 90%, 92%, 95% or 98% transparent to the release wavelength of light, or any range of values therebetween. In some embodiments, the non-photobleached regions that include the photobleachable compound are, are about, are at most, or are at most about, 0.5%, 1%, 2%, 5%, 8%, 10%, 12%, 14%, 15%, 18%, 20% or 25% transparent to the release wavelength of light, or any range of values therebetween. In some embodiments, the substrate the intermittently photobleached layer is disposed over is transparent to the release wavelength of light.

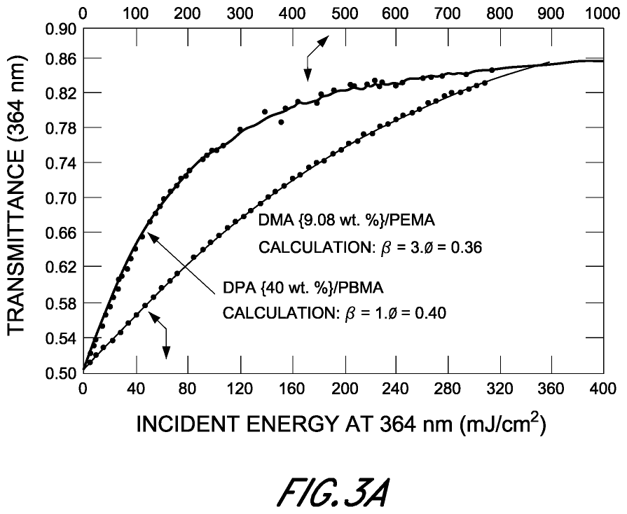

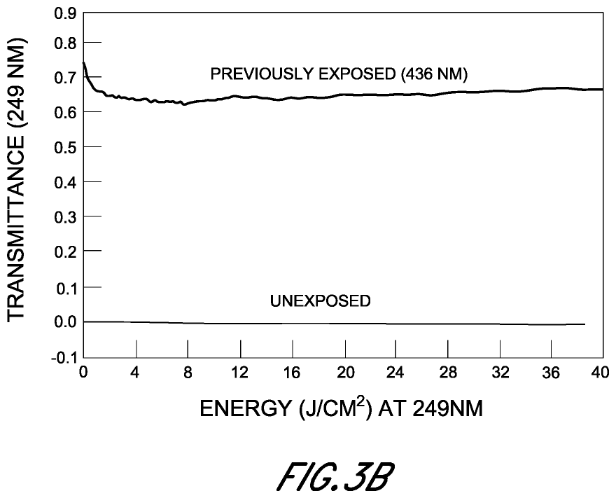

In some embodiments, a mask substrate is deposited with (e.g., coated with) a layer of a photobleachable material (e.g., an anthracene compound incorporated in a polymer matrix, wherein the polymer matrix may have a high oxygen permeability), wherein the photobleachable layer is opaque to a release wavelength of light. The photobleachable layer is irradiated at select locations or regions to bleach the absorption of those regions and form an intermittently photobleached mask comprising select locations of photobleached material. In some embodiments, the select locations may correspond to the locations of select components (e.g., defective chips) on a donor plate. In some embodiments, the bleaching reaction of the photobleachable layer is performed in an atmosphere comprising oxygen (e.g., air, air comprising an excess of oxygen, or an oxygen rich atmosphere). In some embodiments, the bleaching reaction is performed at deep-UV wavelengths (e.g., about 250-270 nm), near-UV wavelengths (e.g., about 360-375 nm), or in blue wavelengths (e.g., 436 nm). In some embodiments, the bleaching wavelength is, or is about, 180 nm, 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 375 nm, 380 nm, 390 nm, 400 nm, 410 nm, 420 nm, 430 nm, 435 nm, 440 nm, 450 nm, 475 nm, 500 nm, 525 nm, 550 nm, 575 nm or 600 nm, or any range of values therebetween. In some embodiments, the photobleachable layer further comprises a sensitizer, such as ketocoumarins. In some embodiments, such as for these wavelengths and at possibly low intensities, the optical pattern may be conveniently supplied by a variety of spatial light modulators. FIG. 3A depicts the photobleaching kinetics for 9,10-dimethylanthracene (“DMA”) in poly(ethyl methacrylate) (“PEMA”) films and 9,10-diphenylanthracene (“DPA”) in poly(butyl methacrylate) (“PBMA”) films. FIG. 3B is a graph showing the stability of oxidized DPA to irradiation in a nitrogen atmosphere by 248 nm KrF excimer laser (approximately 10 ns pulses, —1 mJ/cm²) at 25 pps (reproduced from J. R. Sheats, et al., SPIE Proceedings, vol. 631, pp. 171-177 (March 1986)).

The efficiency of photobleaching, and therefore the throughput of the photomask production process, depends at least in part on diffusion of oxygen into the film during exposure. This phenomenon indicates a requirement for greater irradiation doses in the data in FIGS. 3A and 3B than would have been the case if sufficient oxygen were available. Siloxanes may enhance oxygen permeability of polymers. However, pure siloxanes, especially linear ones such as poly(dimethylsiloxane), are typically not compatible with carbon-based molecules, such as anthracene. However, the two may be made compatible while still achieving high oxygen permeability. In some embodiments, the photobleachable compound comprises siloxane moieties attached to the anthracene, to a hydrocarbon polymer, or a combination thereof. In some embodiments, the photobleachable compound may be substituted at any position of the molecule. In some embodiments, the photobleachable compound may be substituted with a plurality of siloxane groups. In some embodiments, the siloxane or siloxane group may be substituted with oligomeric linear chains, trimethyl silyl groups, and combinations thereof. Photobleachable compound compositions and siloxane substitutions are also disclosed in the U.S. Pat. No. 5,180,655, which is incorporated by reference in its entirety for all purposes. In some embodiments, siloxane groups may be substituted with polyacetylenes (e.g., poly(trimethylsilyl propyne) and poly(4-methyl-2-pentyne)), fluoropolymers, poly(norbornenes), and others as described, for example, by P. M. Budd and N. B. McKeown in Polymer Chemistry, vol. 1, pp. 63-68 (2010), which is incorporated by reference in its entirety for all purposes.

In some embodiments, the photobleachable material comprises a base polymer and a polycyclic aromatic hydrocarbon compound. In some embodiments, the photobleachable compound includes the polycyclic aromatic hydrocarbon compound. In some embodiments, polycyclic aromatic hydrocarbon compounds include acenes, tetracenes, pentacenes, rubrenes, anthradichromenes, dianthrones, and combinations thereof. In some embodiments, the polycyclic aromatic hydrocarbon compound is selected from 9,10-dimethylanthracene (DMA), 9,10-diphenylanthracene (DPA), 1,4,9,10-tetraphenylanthracene, 5,12-diphenyltetracene, and combinations thereof. In some embodiments, the polycyclic aromatic hydrocarbon compound is substituted or unsubstituted. In some embodiments, the polycyclic aromatic hydrocarbon compound is substituted by an alkyl (e.g., C₁₋₁₂ alkyl), an aryl (e.g., C₅₋₁₀ aryl), a siloxane, and combinations thereof. In some embodiments, siloxanes include poly(diphenylsiloxane) (“PDPS”). In some embodiments, the siloxane is substituted. In some embodiments, the siloxane is substituted with polyacetylene, a fluoropolymer, a poly(norbornene), or combinations thereof. In some embodiments, siloxanes may be substituted by poly(trimethylsilyl propyne), poly(4-methyl-2-pentyne), or combinations thereof.

In some embodiments, the base polymer is selected from an acrylate polymer, a siloxane polymer, and combinations thereof. In some embodiments, the acrylate polymer is selected from poly(methyl methacrylate) (PMMA), poly(ethyl methacrylate) (PEMA), poly(butyl methacrylate) (PBMA) and combinations thereof. In some embodiments, the siloxane polymer includes poly(diphenylsiloxane) (“PDPS”). In some embodiments, the siloxane polymer is substituted. In some embodiments, the siloxane polymer is substituted with a group selected from polyacetylene, fluoropolymer, poly(norbornene) and combinations thereof. In some embodiments, the siloxane polymer is substituted with a group selected from poly(trimethylsilyl propyne), poly(4-methyl-2-pentyne), and combinations thereof. In some embodiments, the base polymer is substituted or unsubstituted.

An intermittently photobleached mask comprising regions of photobleachable and photobleached material may then be used during a pre-press transfer process to selectively remove select components (e.g., defective chips). In some embodiments, the transfer process is performed in an atmosphere lacking oxygen (e.g., an inert atmosphere, for example nitrogen) to prevent degradation of the mask. In some embodiments, the same mask can be used to transfer chips from another donor plate into the vacant spots on the target.

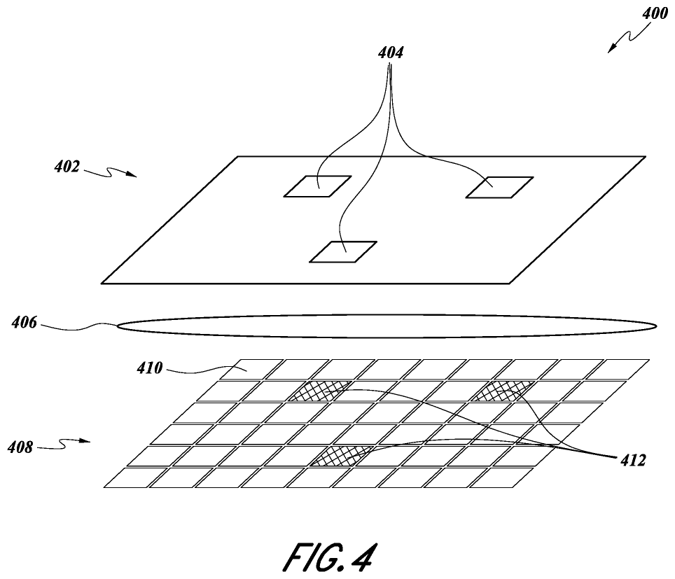

In some embodiments, such intermittently photobleached masks may be used in the same process flow as described with directed laser beams. Before the first intermediate transfer step for component (e.g., chip) spacing with the components (e.g., chips) arranged as shown in FIG. 1A, the defective chips may be removed utilizing an intermittently photobleached mask. FIG. 4 depicts an arrangement 400 for removing select components (e.g., defective chips) using the intermittently photobleached mask 402 disposed over a lens 406 which is disposed over a donor plate 408. The intermittently photobleached mask 402 includes photobleached material regions 404 that act as apertures. In some embodiments, the region of the mask beyond the photobleached material regions 404 comprise photobleachable material. The transfer assembly that includes the donor plate 408 further includes a plurality of components 410 and select components 412, wherein the location of photobleached material regions 404 align with or correspond to the locations and areas of the select components (e.g., defective chips). The components 410 and select components 412 are held to the donor plate 408 by a release layer, wherein at least some of the regions of the release layer underlying the select components 412 may be referred to as select release layer regions. Irradiation of the intermittently photobleached mask 402 (e.g., using a PCA process) projects the image of the photobleached material regions 404 of the mask through the lens 406, while blocking light incident upon the photobleachable regions of the mask beyond the photobleached material regions 404 that comprises a photobleachable compound (e.g., photobleachable dye) that is not bleached and blocks wavelengths of irradiated light. The light that passes through the photobleached material regions 404 irradiate the select release layer regions disposed over select components 412, and causes release (e.g., ejection) of the select components 412 (e.g., defective chips). In some embodiments, the donor plate 408 is transparent and irradiation is directed through the donor plate 408 to the release layer. To fill the resulting vacancies, a similar operation and assembly as shown in FIG. 4 may be carried out on another donor plate, such as the donor plate illustrated in FIG. 1C, using the same intermittently photobleached mask 402 to deposit components (e.g., good dice) on regions of the donor plate 408 previously occupied by select components 412. The transparent or photobleached regions of the mask do not have to correspond to exactly one chip, and in some embodiments entire regions of chips may be selected. This may be of value, for example, with the microLEDs, where the inhomogeneous process conditions which lead to emission wavelengths out of specification typically extend over longer distances than one LED. In some embodiments of arrangements of FIG. 4, the photobleached material regions 404 are instead photobleachable regions, and the photobleachable regions of the mask beyond the photobleached material regions 404 are instead photobleached regions.

An advantage of using an intermittently photobleached mask is that the photobleached optical pattern may be more easily generated compared with either etched metal masks or laser-ablated polymer masks. In embodiments of the PCA process, deep UV light (e.g. 248-260 nm) is used. Additionally, the intensity of the light may be adjusted so as to simultaneously provide the heat necessary for PCA. However, it may be difficult to form such optical patterns on the required length scale directly from digital inputs such as LED arrays, digital micromirror devices, LCD light valves, or other spatial light modulators, which mostly require longer wavelength light and may tolerate only low intensities. For example, ordinary high resolution LCD displays, with for example up to about 1500 subpixels per inch (500 display pixels, subdivided into 3 color subpixels per display pixel) have light emitting areas of about 14 μm area, which is small enough to give uniform selectivity to regions of about 100 μm or less. For higher resolution, microLED arrays may be assembled with pixel pitch of less than 10 μm. Both of these sources are available at all visible wavelengths, and can also be made for 365 nm use. Alternatively, multiple scanning beams in less-dense arrays can be made with near-UV or blue light sources (LEDs or diode lasers, for example, assembled as close to each other as mechanically feasible or convenient). Each discrete light source may be switched on and off appropriately as the array is scanned across the donor plate, in such a way that the throughput is greater than with only one source. This process, despite its extra steps, may be advantageous from the perspective of production economics. The defect-removing process is implemented as part of the preparation of donor plates for use in populating multichip circuits using the PCA process, during which of the order of hundreds (in a non-limiting example from about 100 to about 400) chips are transferred at once to product targets. To obtain desirable economics, this step should be as fast as possible. In the PCA process, this transfer typically requires less than a millisecond, and makes use of a donor plate which contains many thousands of chips (or tens of thousands, depending on the chip size). The donor plate may be economically processed as described during the pre-press sequence to remove and replace defective chips, with much more time spent on each plate than is spent on each product target. Thus the use of a relatively low intensity light source to bleach the mask pattern into a dye may be economically preferable compared to alternatives of serial processing with single laser beams or the fabrication of different metal masks for each defect pattern.

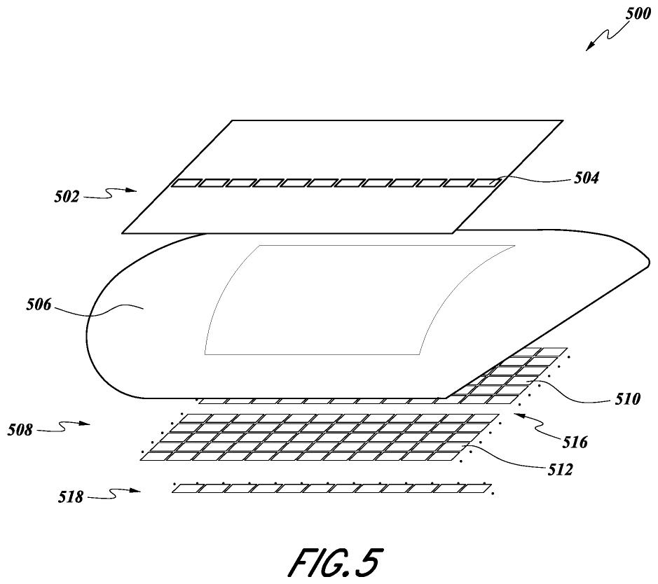

In some embodiments, the intermittently photobleached mask 402 (e.g., anthracene-based selectively photobleachable dye masks) could be used directly as the basis for the optical pattern during PCA operation, without the need to fabricate metal masks. Although a metal mask has greater durability for long production runs, such a metal mask is typically more difficult and time consuming to fabricate. As such, a metal mask with a specific mask pattern may be more suitable for use as the main chip transfer to product units subjected to hundreds of thousands (or more) exposures, during which a polymer may be more likely prone to damage. FIG. 5 depicts a standard pre-press optical arrangement 500, that may be used for adjusting the spacing of rows and columns of chips. A mask 502 includes a plurality of apertures 504 in a single row (or column), wherein the mask 502 is disposed over a lens 506 (shown as a cylindrical lens) which is disposed over a donor plate 508. In some embodiments, the aperture may instead include a single open rectangular aperture in place of the plurality of apertures 504. Light is passed through the plurality of apertures 504 and then through the lens 506 to the donor plate 508 to release the release layer disposed on the select row of components 518, while not exposing components 510 and 512 of the donor plate 508. In some embodiments, the mask remains stationary, while the donor plate moves relative to it for each transfer to select each new row. In the absence of select components (e.g., defective chips), this rectangle mask may be the same for all chips of that type and may be used many times.

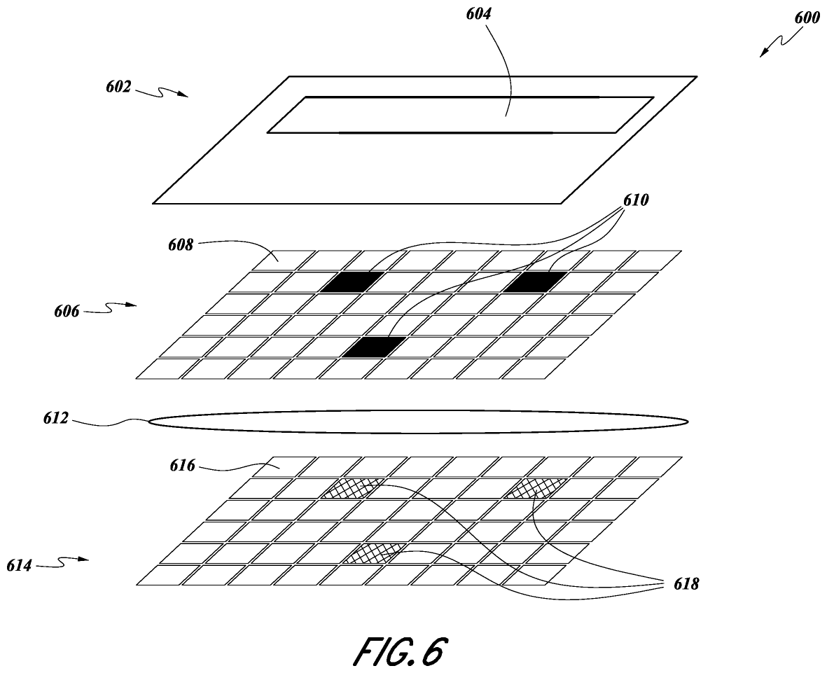

Utilizing two masks (e.g., a metal mask and an intermittently photobleached mask) may be able to speed up component transfer processes. For example, using a metal mask and an intermittently photobleached mask may allow select components (e.g., defective chips) to be removed or eliminated concurrently during a first pre-press step, such as the first pre-press step shown in FIGS. 1A and 1B. An embodiment of such a double masked arrangement 600 is illustrated in FIG. 6. Similar to the mask depicted in FIG. 5, a first mask 602 (e.g., metal mask) is depicted with a rectangular slit opening 604 configured to define a row to image light onto a second mask 606 and then onto components (e.g., chips) of the donor plate 614 to induce release of the components for transfer. In some embodiments, the slit opening 604 is a slot whose width is the same or similar as one dimension of the components (e.g., chips) being transferred. The second mask 606 includes photobleached material regions 608 that act as apertures, and photobleachable regions 610 that comprises a photobleachable compound (e.g., photobleachable dye) that is not bleached and blocks wavelengths of irradiated light. Row by row light is passed through the first mask 602, through the photobleached regions 608 and blocked by the photobleachable regions 610 of the second mask 606, then through the lens 612 to the select components 616 of a donor plate 614. In some embodiments, then the second mask 606 and the donor plate 614 are moved simultaneously relative to the rectangular slit opening 604 of the first mask 602 to transfer select components 616 to a substrate with new row spacing. The photobleachable regions 610 of the second mask 606 are not bleached and correspond to the locations of the non-select components 618 (e.g., defective components) of the donor plate 614. As such, irradiation of the release layer of the donor plate through the double mask arrangement 600 causes the release layer disposed on the select components 616 (e.g., chips) to release and allows the select components 616 to be transferred, while the non-select components 618 (e.g., defective components) remain attached to the donor plate 614 by the remaining release layer. Thus, once the select components 616 are transferred to a second substrate (e.g. second donor plate), the second donor plate may have a similar component pattern to the device depicted in FIG. 1B. In some embodiments, an arrangement and/or process as described with regard to FIGS. 4 and/or 6 may be utilized in a final pre-press transfer to fill the vacancies of the second substrate with the select components 616, and for example achieve a component distribution as shown FIG. 1C. In some embodiments of double masked arrangements of FIG. 6, the photobleached regions 608 are instead photobleachable regions, and the photobleachable regions 610 are instead photobleached regions.

As such, by utilizing the double mask arrangement described at least one step of a transfer process with select components, such as the transfer process of FIGS. 1A-1C, may be eliminated. Although the mechanics and optics of a double mask arrangement and the process of utilizing the arrangement may be more complex (e.g., two masks, additional imaging lenses that may be required, and/or additional corresponding alignments), such an approach may advantageously improve production throughput by decreasing the number of steps and therefore processing time.

In some embodiments (e.g., for donor plates with relatively small numbers of defects), the photobleachable dye may be coated directly onto a metal masks to form a combination mask. In some embodiments, the combination mask may be used for the main transfer.

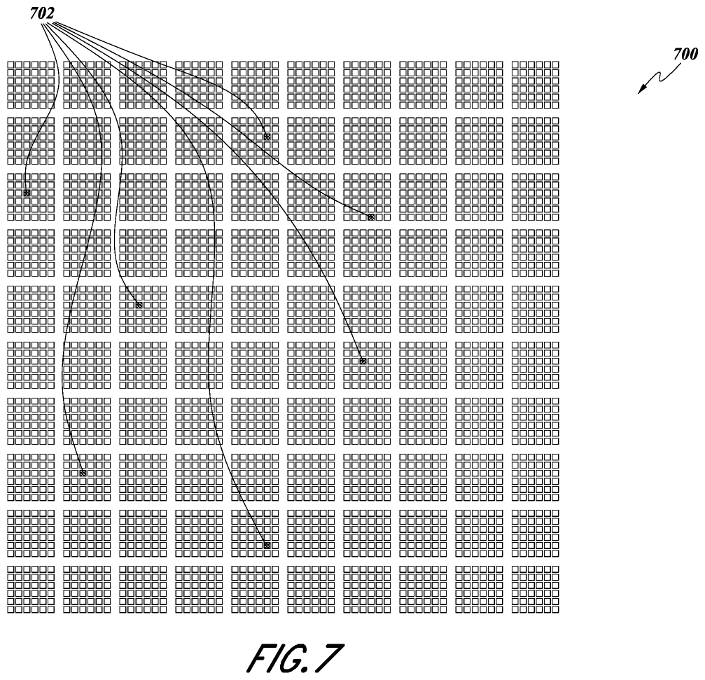

In this embodiment, the defective chips are carried through the pre-press operations and are still on the donor plate which carries out the final transfer to product units. FIG. 7 is an illustration of a donor plate 700 with select components 702 that that are selected to be removed. In some embodiments, the donor plate 700 is configured for placing at least one of 36 components (e.g., chips) from each 100 subarrays (each 3 mm×3 mm), simultaneously onto 100 devices (e.g., product circuits, each 20×20 mm). The wafer from which the components (e.g., chips) were taken is considered to have had 7 select components 702 (e.g., defects). In some embodiments, the components (e.g., chips) are transferred in a sequence; (1,1), (1,2), 1,3), . . . , (2,1), (2,2), . . . , (6,6) where the numbers refer to the row and column positions within each subarray. When a select component (e.g., defective chip) on the donor plate is aligned with a target position of a device, a mask that normally selects one or more components (e.g., chips) from each subarray is moved out, and replaced by a mask (e.g., intermittent photobleached mask or double mask arrangement) which has the position of the select component blocked, while the other positions are transparent. For example, the (3,3) position of the subarrays is defective in 4 places, and therefore a mask switch can be performed 4 times for the 4 subarrays which can be populated by this donor plate.

In some embodiments, where a donor plate does not include select components (e.g., defective chips) in the set or subarray which is transferred to devices or product units in any one exposure, a typical mask (e.g., metal slit mask) may be used. Using FIG. 7 as an example, this would be true for 32 exposures, wherein each exposure transfers 100 chips. In some embodiments, according to the defect pattern, where one or more select components (e.g., defective chips) are in locations where they would be transferred and incorporated into the product, the regular mask is removed and an intermittently photobleached mask (i.e., dye-coated mask) with the relevant defect pattern bleached into it is inserted and utilized so that only non-select components (e.g., good dice) are transferred when the release layer is exposed to light. In some embodiments, substrates with vacancies are then shunted into a separate flow where they are filled from a donor plate with known good dice. In some embodiments, the changing of masks may be accomplished at the same time as the changing of substrates, and only a small additional increment of alignment time is needed compared to the normal process. In some embodiments (e.g., embodiments with small defect densities), this changeover is relatively infrequent and therefore may be advantageous in the production process.

The 4 substrates that hold the components with vacancies in the (3,3) position may be put in a separate stream and the (3,3) position vacancies may be filled in a make-up step with components from another donor plate. In some embodiments, a “make-up” donor place is required to supply the known good dice to fill in vacancies. In some embodiments, when this is done in parallel (i.e., not with a directed laser beam), over time the donor plate will become depleted in random positions and it will no longer be possible to have a good die aligned with every vacancy to be transferred in one exposure. With some reduction in throughput, the remaining chips on the depleted donor plate can be transferred using a mask with a single aperture which is moved to align to each chip to be transferred. In some embodiments, a directed laser beam may be used. In some embodiments, these modes of operation may be combined; for example if there are 10 vacancies, at some point only 9 chips will be available for simultaneous transfer. These 9 can be transferred in one exposure, and the tenth vacancy can be filled with the single-chip mode.

In some embodiments, although embodiments have been described with reference to the transfer of individual rows or columns of components (e.g., chips) in the pre-press process step, any number of rows/columns and/or patterns of components may be utilized. For example, multiple rows may be transferred simultaneously resulting in blocks or sub-arrays of components (e.g., chips) on a donor plate.

While certain embodiments have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products. For example, any of the components for an energy storage system described herein can be provided separately, or integrated together (e.g., packaged together, or attached together) to form an energy storage system.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount, depending on the desired function or desired result.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

The headings provided herein, if any, are for convenience only and do not necessarily affect the scope or meaning of the devices and methods disclosed herein.

What is claimed is:

1. An intermittently photobleached mask, comprising:
an intermittently photobleached layer comprising a photobleachable material;
wherein the intermittently photobleached layer comprises photobleached regions at least partially transparent to a release wavelength of light; and
wherein the intermittently photobleached layer comprises non-photobleached regions substantially opaque to the release wavelength of light; and
a substrate disposed over the intermittently photobleached layer.

2. The mask of claim 1, wherein the photobleachable material comprises a base polymer and a polycyclic aromatic hydrocarbon compound.

3. The mask of claim 2, wherein the polycyclic aromatic hydrocarbon compound is selected from the group consisting of an acene, a tetracene, a pentacene, a rubrene, an anthradichromene, a dianthrone, and combinations thereof.

4. The mask of claim 2, wherein the polycyclic aromatic hydrocarbon compound is selected from the group consisting of 9,10-dimethylanthracene (DMA), 9,10-diphenylanthracene (DPA), 1,4,9,10-tetraphenylanthracene, 5,12-diphenyltetracene, and combinations thereof.

5. The mask of claim 2, wherein the polycyclic aromatic hydrocarbon compound is substituted by a substituent selected from the group consisting of an alkyl, an aryl, a siloxane, and combinations thereof.

6. The mask of claim 5, wherein the siloxane is substituted with a substituent selected from the group consisting of a polyacetylene, a fluoropolymer, a poly(norbornene) and combinations thereof.

7. The mask of claim 2, wherein the base polymer comprises a polymer selected from the group consisting of an acrylate polymer, a siloxane polymer, and combinations thereof.

8. The mask of claim 7, wherein the acrylate polymer is selected from the group consisting of poly(methyl methacrylate) (PMMA), poly(ethyl methacrylate) (PEMA), poly(butyl methacrylate) (PBMA) and combinations thereof.

9. The mask of claim 1, wherein the release wavelength of light is from about 250-370 nm.

10. The mask of claim 1, wherein the photobleached regions are at least about 60% transparent to the release wavelength of light.

11. The mask of claim 1, wherein the non-photobleached regions are at most about 10% transparent to the release wavelength of light.

12. The mask of claim 1, wherein the substrate is transparent to the release wavelength of light.

13. A process of using the intermittently photobleached mask of claim 1, comprising:
disposing the intermittently photobleached mask over a transfer assembly comprising a donor plate, a release layer disposed over the donor plate and plurality of components disposed over the release layer;
wherein the plurality of components comprise at least one select component disposed over and at least partially overlapping with at least one select release layer region; and
wherein the photobleached regions are aligned with the at least one select release layer region; and
directing a release wavelength of light through the photobleached regions to the at least one release layer region thereby degrading the at least one release layer region and forming at least one released component.

14. The process of claim 13, further comprising transferring the at least one released component to a receiving substrate.

15. The process of claim 13, wherein the at least one released component comprises a plurality of released components, and wherein the plurality of released components are transferred simultaneously to a receiving substrate.

16. The process of claim 13, further comprising directing the release wavelength of light through a second mask to the photobleached regions.

17. The process of claim 16, wherein the second mask prevents exposure of additional photobleached regions of the intermittently photobleached mask to the release wavelength of light.

18. The process of claim 16, further comprising moving the second mask relative to the intermittently photobleached mask and the transfer assembly subsequent to directing the release wavelength of light through the second mask, wherein relative positions of the intermittently photobleached mask and the transfer assembly are substantially the same.

19. The process of claim 13, further comprising applying heat to the at least one release layer region.

20. The process of claim 13, wherein the release wavelength of light is directed through the substrate to the at least one release layer region.

21. A process of fabricating an intermittently photobleached mask, comprising:
providing photobleachable layer disposed over a substrate, wherein the photobleachable layer is substantially opaque to a release wavelength of light;
exposing the photobleachable layer to an atmosphere comprising oxygen gas; and
irradiating select regions of the photobleachable layer to form an intermittently photobleached layer comprising photobleached regions at least partially transparent to the release wavelength of light.

22. The process of claim 21, further comprising depositing the photobleachable layer over the substrate.

23. The process of claim 21, wherein the atmosphere is air or an oxygen rich atmosphere.

24. The process of claim 21, wherein irradiation is performed at a bleaching wavelength from 250-550 nm.
